(19) United States
(12) Patent Application Publication
(10) Pub. No.: US 2026/0371626 A1
(43) Pub. Date: Nov. 19, 2026

(54) HETEROJUNCTION BIPOLAR TRANSISTORS FORMED INSIDE A TRENCH IN A SEMICONDUCTOR LAYER

(71) Applicant: GlobalFoundries Singapore Pte. Ltd., Singapore (SG)

(72) Inventors: Hao Nong, Singapore (SG); Kien Seen Daniel Chong, Singapore (SG); Vibhor Jain, Clifton Park, VT (US); John J. Pekarik, Underhill, VT (US); Xinshu Cai, Singapore (SG); Seow Wei Lai, Singapore (SG)

(21) Appl. No.: 19/211,427

(22) Filed: May 19, 2025

(51) Int. Cl. H10D 10/80; H10D 10/01; H10D 30/01; H10D 62/10; H10D 84/60

(52) U.S. Cl. CPC H10D 10/80; H10D 10/021; H10D 30/027; H10D 62/124; H10D 84/60

(57) ABSTRACT

Structures including a heterojunction bipolar transistor and methods of forming a structure including a heterojunction bipolar transistor. The structure comprises a semiconductor substrate including a top surface and a trench having a bottom that is recessed relative to the top surface. The structure further comprises first and second trench isolation regions in the semiconductor substrate. The first trench isolation region includes a portion with a sidewall that surrounds the trench, the second trench isolation region surrounds the first trench isolation region, and the second trench isolation region is spaced from the first portion of the first trench isolation region by a portion of the semiconductor substrate that adjoins the top surface. The device structure includes first and second semiconductor layers inside the trench and a doped region in the portion of the semiconductor substrate. The first and second semiconductor layers adjoin along a p-n junction.

### BACKGROUND

The present disclosure relates to semiconductor device fabrication and integrated circuits and, more specifically, to structures including a heterojunction bipolar transistor and methods of forming a structure including a heterojunction bipolar transistor.

A bipolar junction transistor is a multi-terminal electronic device that includes an emitter, a collector, and an intrinsic base arranged between the emitter and collector. In an NPN bipolar junction transistor, the emitter and collector are comprised of n-type semiconductor material, and the intrinsic base is comprised of p-type semiconductor material. In a PNP bipolar junction transistor, the emitter and collector are comprised of p-type semiconductor material, and the intrinsic base is comprised of n-type semiconductor material. During operation, the base-emitter junction is forward biased, the base-collector junction is reverse biased, and the collector-emitter current may be controlled with the base-emitter voltage.

A heterojunction bipolar transistor is a variant of a bipolar junction transistor in which the semiconductor materials of the terminals have different bandgaps, which creates heterojunctions. For example, the collector and/or emitter of a heterojunction bipolar transistor may be constituted by silicon, and the intrinsic base of a heterojunction bipolar transistor may be constituted by silicon-germanium, which is characterized by a narrower band gap than silicon.

Improved structures including a heterojunction bipolar transistor and methods of forming a structure including a heterojunction bipolar transistor are needed.

### SUMMARY

In an embodiment of the invention, a structure comprises a semiconductor substrate including a top surface and a trench having a bottom that is recessed relative to the top surface. The structure further comprises a first trench isolation region and a second trench isolation region in the semiconductor substrate. The first trench isolation region includes a portion having a sidewall that surrounds the trench, the second trench isolation region surrounds the first trench isolation region, and the second trench isolation region is spaced from the first portion of the first trench isolation region by a portion of the semiconductor substrate that adjoins the top surface. The device structure includes a first semiconductor layer inside the trench, a second semiconductor layer inside the trench, and a doped region in the portion of the semiconductor substrate. The first semiconductor layer and the second semiconductor layer adjoin along a p-n junction.

In an embodiment of the invention, a structure comprises a semiconductor substrate including a top surface and a trench having a bottom that is recessed relative to the top surface, a first trench isolation region in the semiconductor substrate, and a device structure including a first semiconductor layer inside the trench and a second semiconductor layer inside the trench. The first trench isolation region includes a portion having a sidewall that adjoins the trench, and the portion of the first trench isolation region extends from the top surface of the semiconductor substrate to a first maximum depth in the semiconductor substrate. The first semiconductor layer and the second semiconductor layer adjoin along a p-n junction. The structure further comprises a second trench isolation region in the semiconductor layer. The second trench isolation region is laterally offset from the sidewall of the first portion of the first trench isolation region toward the device structure, the second trench isolation region extends from the top surface to a second maximum depth in the semiconductor substrate, and the second maximum depth is greater than the first maximum depth.

In an embodiment of the invention, a method comprises forming a trench in a semiconductor substrate, forming a first trench isolation region in the semiconductor substrate, and forming a second trench isolation region in the semiconductor substrate. The semiconductor layer has a top surface, the trench has a bottom that is recessed relative to the top surface, the first trench isolation region includes a portion having a sidewall that surrounds the trench, the second trench isolation region surrounds the first trench isolation region, and the second trench isolation region is spaced from the portion of the first trench isolation region by a portion of the semiconductor substrate that adjoins the top surface. The method further comprises forming a device structure including a first semiconductor layer inside the trench, a second semiconductor layer inside the trench, and a doped region in the portion of the semiconductor substrate. The first semiconductor layer and the second semiconductor layer adjoin along a p-n junction.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a cross-sectional view of a structure at an initial fabrication stage of a processing method in accordance with embodiments of the invention.

FIG. 2 is a cross-sectional view of the structure at a fabrication stage of the processing method subsequent to FIG. 1.

FIG. 3 is a cross-sectional view of the structure at a fabrication stage of the processing method subsequent to FIG. 2.

FIG. 4 is a cross-sectional view of the structure at a fabrication stage of the processing method subsequent to FIG. 3.

FIG. 5 is a cross-sectional view of a structure in accordance with embodiments of the invention.

FIG. 6 is a cross-sectional view of a structure at an initial fabrication stage of a processing method in accordance with embodiments of the invention.

FIG. 7 is a cross-sectional view of the structure at a fabrication stage of the processing method subsequent to FIG. 6.

FIG. 8 is a cross-sectional view of the structure at a fabrication stage of the processing method subsequent to FIG. 7.

FIG. 9 is a cross-sectional view of a structure in accordance with embodiments of the invention.

FIG. 10 is a cross-sectional view of a structure in accordance with embodiments of the invention.

### DETAILED DESCRIPTION

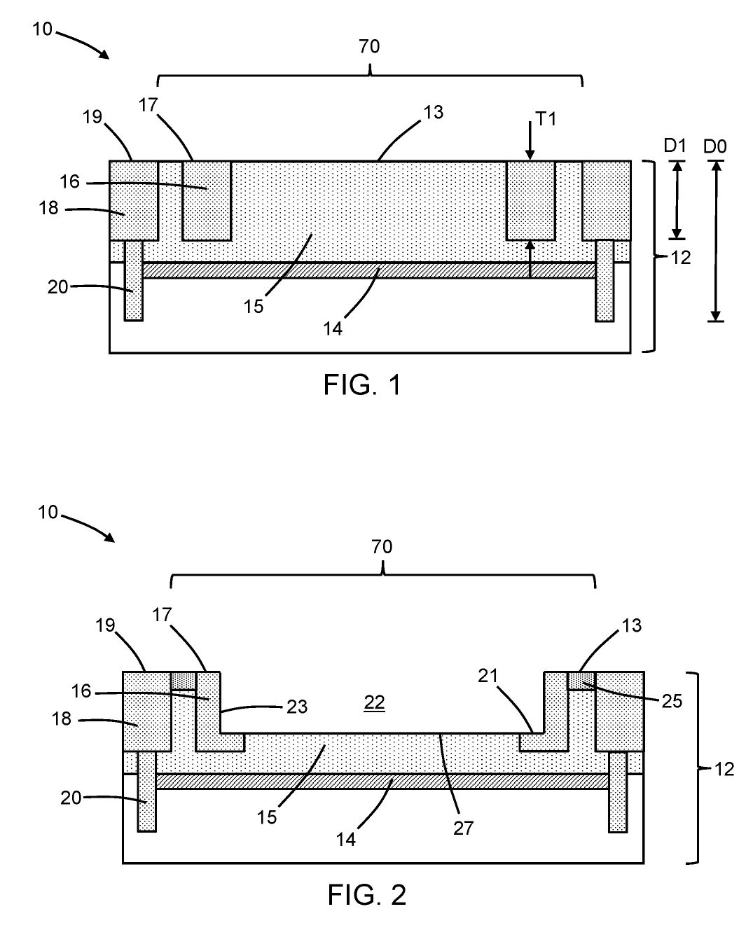

With reference to FIG. 1 and in accordance with embodiments of the invention, a structure 10 includes a semiconductor substrate 12, a well 14 in the semiconductor substrate 12, shallow trench isolation regions 16, 18, and a deep trench isolation region 20. The semiconductor substrate 12, which may be a bulk substrate that includes a semiconductor layer 15, may be comprised of a semiconductor material, such as single-crystal silicon, and may be lightly doped p-type. In an embodiment, the well 14 may be doped with a concentration of an n-type dopant, such as arsenic or phosphorus, such that the well 14 has n-type conductivity. In an embodiment, the well 14 may be formed by introducing the n-type dopant by ion implantation into the semiconductor substrate 12. The implantation conditions, such as ion species, dose, and kinetic energy, may be selected to tune the electrical and physical characteristics of the well 14. The semiconductor layer 15, which may be formed by an epitaxial growth process after the well 14 is formed, may be doped with a concentration of an n-type dopant, such as arsenic or phosphorus, such that the semiconductor layer 15 has n-type conductivity.

The shallow trench isolation region 18 and the deep trench isolation region 20 surround a device region 70 of the semiconductor substrate 12 in which a junction device, such as a heterojunction bipolar transistor, is subsequently formed. The shallow trench isolation region 16 is arranged inside the device region 70 and is surrounded by the shallow trench isolation region 18 and the deep trench isolation region 20. The deep trench isolation region 20 extends through the semiconductor layer 15 and into the underlying semiconductor substrate 12. The well 14 spans across the full width dimension of the portion of the semiconductor layer 15 surrounded by the deep trench isolation region 20. A portion of the semiconductor layer 15 is arranged in the device region 70 above the well 14.

The deep trench isolation region 20 extends to a maximum depth D0 relative to a top surface 13 of the semiconductor substrate 12. In an embodiment, the shallow trench isolation region 16 and the shallow trench isolation region 18 may extend to the same maximum depth D1 relative to the top surface 13 of the semiconductor substrate 12. The maximum depth D0 of the deep trench isolation region 20 is greater than maximum depth D1 of the shallow trench isolation regions 16, 18.

The shallow trench isolation region 16 has a top surface 17 that may be planar. The shallow trench isolation region 18 has a top surface 19 that may be planar. In an embodiment, the top surface 17 may be coplanar with the top surface 19. In an embodiment, the top surface 17 may be substantially coplanar with the top surface 19. In an embodiment, the top surface 17 may be coplanar with a top surface 13 of the semiconductor substrate 12. In an embodiment, the top surface 17 may be substantially coplanar with the top surface 13 of the semiconductor substrate 12. In an embodiment, the top surface 19 may be coplanar with the top surface 13 of the semiconductor substrate 12. In an embodiment, the top surface 19 may be substantially coplanar with the top surface 13 of the semiconductor substrate 12.

The deep trench isolation region 20 may be formed by patterning a deep trench with lithography and etching processes, depositing a liner on the sidewall of the deep trench, depositing a core to fill the space inside the liner, and planarizing and/or recessing the core and liner. In an embodiment, the liner of the deep trench isolation region 20 may comprise a dielectric material, such as silicon oxide (e.g., silicon dioxide), and the core of the deep trench isolation region 20 may comprise a semiconductor material, such as doped polysilicon. The shallow trench isolation regions 16, 18 may be formed by patterning shallow trenches with lithography and etching processes, depositing a dielectric material to fill the shallow trenches, and planarizing and/or recessing the dielectric material. In an embodiment, the shallow trench isolation regions 16, 18 may be comprised of a dielectric material, such as an oxide of silicon like silicon dioxide. The shallow trench isolation region 18, which may be formed subsequent to the deep trench isolation region 20, may be arranged between the deep trench isolation region 20 and the top surface 13 of the semiconductor substrate 12.

With reference to FIG. 2 in which like reference numerals refer to like features in FIG. 1 and at a subsequent fabrication stage, a doped region 25 may be formed in a portion of the semiconductor layer 15 between the shallow trench isolation region 16 and the shallow trench isolation region 18. The doped region 25 may adjoin the top surface 13 of the semiconductor substrate 12. In an embodiment, the doped region 25 may be formed by, for example, ion implantation of a dopant with given implantation conditions. A patterned implantation mask may be formed to define a selected area that is exposed for implantation by ions. The implantation mask may include a layer of an organic photoresist that is applied and patterned to form openings exposing the selected area and determining, at least in part, the location and horizontal dimensions of the doped region 25. The implantation mask has a thickness and stopping power sufficient to block the implantation of ions in masked areas. The implantation conditions, such as ion species, dose, and kinetic energy, may be selected to tune the electrical and physical characteristics of the doped region 25. In an embodiment, the doped region 25 may be heavily doped with a concentration of an n-type dopant, such as phosphorus or arsenic, to provide n-type electrical conductivity.

A trench 22 may be formed as a recess that penetrates partially through the semiconductor layer 15 of the semiconductor substrate 12 and partially through the shallow trench isolation region 16. The trench 22 may be patterned by lithography and etching processes. The trench 22 has a bottom 27 that is spaced in a vertical direction relative to the top surface 13 of the semiconductor substrate 12. The semiconductor layer 15 of the semiconductor substrate 12 has a surface that adjoins the bottom 27 of the trench 22 and that may be coplanar with the bottom 27 of the trench 22.

The trench 22 extends to a maximum depth that is less than the maximum depth D1. The trench 22 extends through a portion of the shallow trench isolation region 16. The shallow trench isolation region 16 has a non-recessed portion for which the top surface 17 remains coplanar with the top surface 19 of the shallow trench isolation region 18 and/or with the top surface 13 of the semiconductor substrate 12. The shallow trench isolation region 16 has a portion that is recessed relative to the top surface 17 and the recessed portion has a top surface 21 that is coplanar or substantially coplanar with the bottom 27 of the trench 22 and therefore with coplanar or substantially coplanar with the surface of the semiconductor layer 15 that adjoins the bottom 27 of the trench 22. The shallow trench isolation region 16 has a sidewall 23 that extends from the top surface 17 of the non-recessed portion to the top surface 21 of the recessed portion. The recessed portion of the shallow trench isolation region 16, which is reduced in thickness, may be considered to constitute an ultra-shallow trench isolation region.

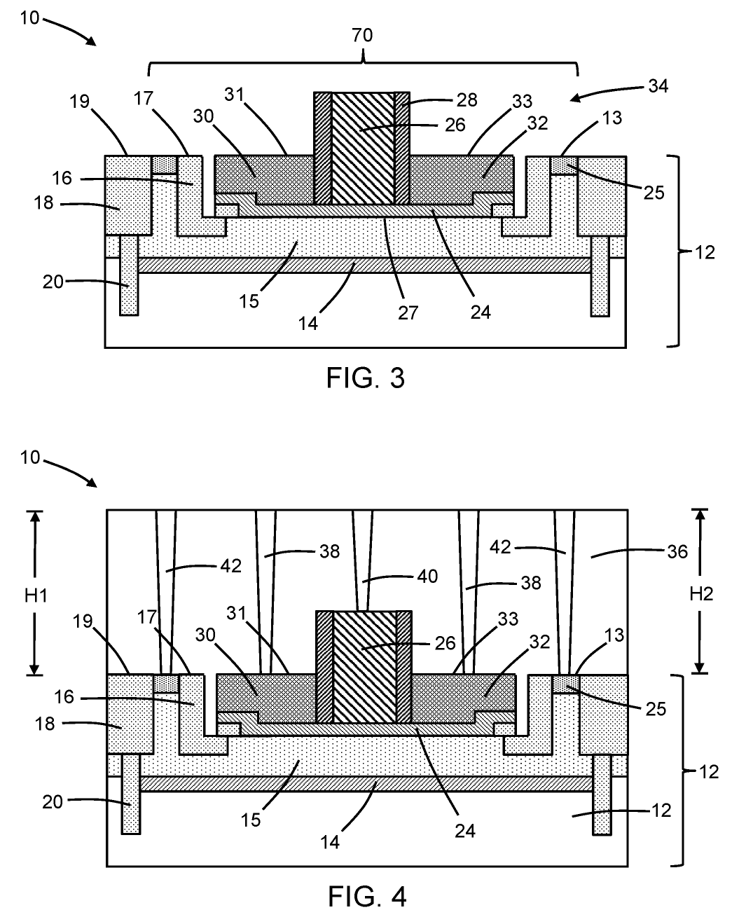

With reference to FIG. 3 in which like reference numerals refer to like features in FIG. 2 and at a subsequent fabrication stage, a base layer 24 and an emitter 26 of a heterojunction bipolar transistor 34 may be formed inside the trench 22 with the emitter 26 positioned on the base layer 24. Dielectric spacers 28 comprised of an electrical insulator may be formed adjacent to the side edges of the emitter 26. The base layer 24 and the emitter 26 may be spaced inwardly from the sidewall 23 (FIG. 2) of the shallow trench isolation region 16.

The base layer 24 may be formed by epitaxially growing or depositing a layer comprised of a semiconductor material and patterning the layer with lithography and etching processes. In an embodiment, the base layer 24 may be comprised of silicon-germanium including silicon and germanium with the silicon content ranging from 95 atomic percent to 50 atomic percent and the germanium content ranging from 5 atomic percent to 50 atomic percent. The base layer 24 may be doped with a concentration of a dopant, such as a p-type dopant (e.g., boron) that provides p-type electrical conductivity.

The emitter 26 may be comprised of a heavily-doped semiconductor material, such as polysilicon that is heavily doped with a concentration of a n-type dopant (e.g., phosphorus or arsenic) to provide n-type electrical conductivity. The emitter 26 may be formed by epitaxially growing or depositing a layer comprised of a semiconductor material and patterning the layer with lithography and etching processes.

The base layer 24 overlaps with an underlying portion of the semiconductor layer 15 providing a portion of the collector of the heterojunction bipolar transistor 34, and the emitter 26 overlaps with an underlying portion of the base layer 24. The base layer 24 adjoins the overlapped portion of the semiconductor layer 15 along a p-n junction, and the emitter 26 adjoins the overlapped portion of the base layer 24 along a p-n junction.

The base layer 24 is positioned in a vertical direction between the emitter 26 and an underlying portion of the semiconductor layer 15. The base layer 24 is positioned in a vertical direction fully below the top surface 13 of the semiconductor substrate 12. A portion of the emitter 26 is positioned in a vertical direction fully below the top surface 13 of the semiconductor substrate 12. The emitter 26 may include another portion that is positioned in the vertical direction fully above the top surface 13 of the semiconductor substrate 12.

Semiconductor layers 30, 32 are formed as raised features on respective portions of the base layer 24 that are exposed adjacent to the opposite sides of the emitter 26. The dielectric spacers 28 are positioned between the emitter 26 and the semiconductor layers 30, 32. The semiconductor layers 30, 32 may be comprised of a semiconductor material, such as silicon or silicon-germanium, and the semiconductor layers 30, 32 may be concurrently formed by a selective epitaxial growth process. The semiconductor layers 30, 32 may be doped (e.g., heavily doped) with a concentration of a dopant, such as a p-type dopant (e.g., boron) to provide p-type electrical conductivity.

The semiconductor layer 30 may have a top surface 31 that is separated from the base layer 24 by the full thickness of the semiconductor layer 30. The semiconductor layer 32 may have a top surface 33 that is separated from the base layer 24 by the full thickness of the semiconductor layer 32. In an embodiment, the top surface 31 may be coplanar with the top surface 33. In an embodiment, the top surface 31 may be coplanar with the top surface 13 of the semiconductor substrate 12. In an embodiment, the top surface 31 may be substantially coplanar with the top surface 13 of the semiconductor substrate 12. In an embodiment, the top surface 33 may be coplanar with the top surface 13 of the semiconductor substrate 12. In an embodiment, the top surface 33 may be substantially coplanar with the top surface 13 of the semiconductor substrate 12. In an embodiment, the top surface 31 and the top surface 33 may be coplanar with the top surface 13 of the semiconductor substrate 12. In an embodiment, the top surface 31 and the top surface 33 may be substantially coplanar with the top surface 13 of the semiconductor substrate 12.

The doped region 25 provides a collector contact region of the heterojunction bipolar transistor 34 that is coupled to the portion of the semiconductor layer 15 that adjoins the base layer 24. The semiconductor layers 30, 32 may provide an extrinsic base of the heterojunction bipolar transistor 34 that is used to contact the base layer 24. The well 14 may provide a sub-collector of the heterojunction bipolar transistor 34.

With reference to FIG. 4 in which like reference numerals refer to like features in FIG. 3 and at a subsequent fabrication stage, middle-of-line processing and back-end-of-line processing follow, which includes deposition of a dielectric layer 36 and the formation of contacts 38, 40, 42 in the dielectric layer 36. The contacts 38 are coupled to the semiconductor layers 30, 32 of the heterojunction bipolar transistor 34, the contact 40 is coupled to the emitter 26 of the heterojunction bipolar transistor 34, and the contacts 42 are coupled by the doped region 25 to the collector of the heterojunction bipolar transistor 34 represented by the portion of the semiconductor layer 15 surrounded by the well 14, the shallow trench isolation region 18, and the deep trench isolation region 20. The contacts 38, 40, 42 may be comprised of a metal, such as tungsten, and the top surfaces 31, 33, the portion of the top surface 13 of the semiconductor substrate 12 over the doped region 25, and the emitter 26 may be capped by a silicide layer (not shown).

The contacts 38 may have a height H1 relative to the top surfaces 31, 33 of the semiconductor layers 30, 32, and the contacts 42 may have a height H2 relative to the top surface 13 of the semiconductor substrate 12 that is planar or substantially coplanar with the top surfaces 31, 33. In an embodiment, the height H1 may be equal to the height H2. In an embodiment, the height H1 may be substantially equal to the height H2.

In an alternative embodiment, the heterojunction bipolar transistor 34 may be replaced by a different type of device structure, such as a silicon-controlled rectifier or a vertical diode, that also includes one or more p-n junctions.

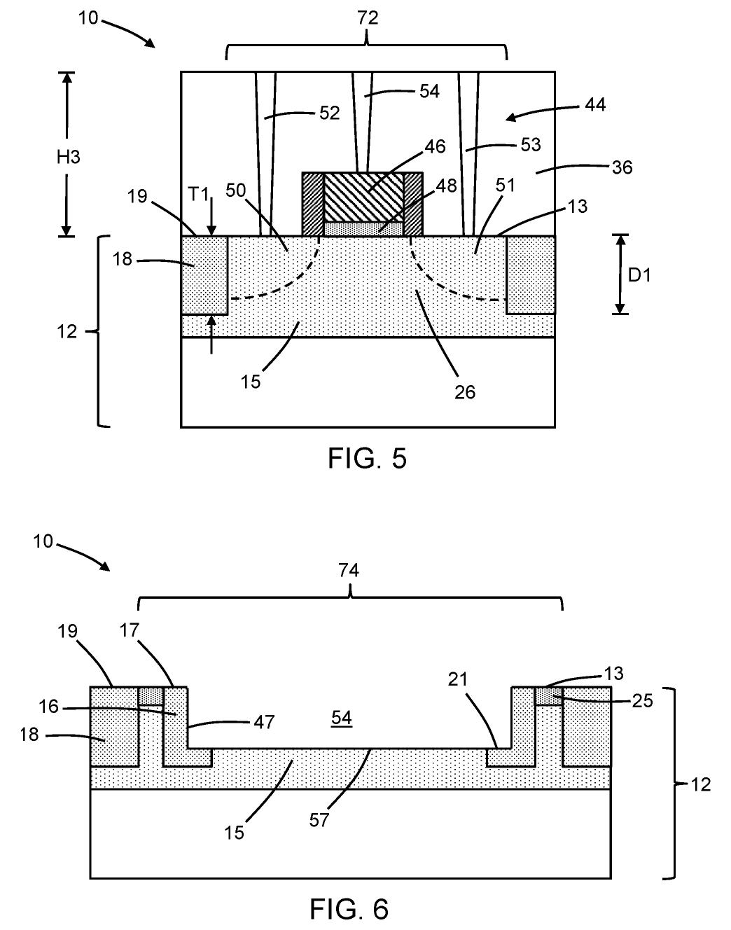

With reference to FIG. 5 and in accordance with alternative embodiments, a field-effect transistor 44 may be fabricated by front-end-of-line processing in a device region 72 of the semiconductor layer 15 that is adjacent to the device region 70. The field-effect transistor 44 may include a gate electrode 46 and a gate dielectric layer 48 formed on the semiconductor layer 15 by depositing a layer stack and patterning the layer stack with photolithography and etching processes. The gate electrode 46 may be comprised of an electrical conductor, such as doped polycrystalline silicon (i.e., doped polysilicon) or a work function metal, and the gate dielectric layer 48 may be comprised of an electrical insulator, such as silicon oxide (e.g., silicon dioxide) or hafnium oxide. The field-effect transistor 44 may include source/drain regions 50, 51 and sidewall spacers on the gate electrode 46. The field-effect transistor 44 may be either a p-type field-effect transistor in which the source/drain regions 50, 51 are characterized by p-type conductivity or an n-type field-effect transistor in which the source/drain regions 50, 51 are characterized by n-type conductivity.

Contacts 52, 53 may formed in the dielectric layer 36. The contacts 52, 53 may be respectively coupled to the source/drain regions 50, 51, and the contact 53 may be coupled to the gate electrode 46. The contacts 52, 53 may have a height H3 relative to the top surface 13 of the semiconductor substrate 12. In an embodiment, the height H3 may be equal to the height H2 (FIG. 4). In an embodiment, the height H3 may be substantially equal to the height H2. In an embodiment, the height H3 may be equal to the height H1 (FIG. 4). In an embodiment, the height H3 may be substantially equal to the height H1. In an embodiment, the height H3 may be equal to the height H1 and the height H2. In an embodiment, the height H3 may be substantially equal to the height H1 and the height H2.

The compatibility of the architecture of the heterojunction bipolar transistor 34 (FIG. 4) with the field-effect transistor 44, when integrated in a layout on the same semiconductor substrate 12, may be improved by recessing the heterojunction bipolar transistor 34 relative to the field-effect transistor 44. The heterojunction bipolar transistor 34 may be characterized by high performance metrics, such as a high value of the transit frequency and/or a high value of the maximum oscillation frequency, and the heterojunction bipolar transistor 34 may be formed without impacting the performance and reliability of the field-effect transistor 44. The equalization of the height H3 with the height H1 and the height H2 may function to improve the performance of the field-effect transistor 44.

The top surface 19 of the shallow trench isolation region 18 in the device region 72 may be coplanar or substantially coplanar with the top surface 19 of the shallow trench isolation region 18 in the device region 70 and coplanar or substantially coplanar with the top surface 17 of the non-recessed portion of the shallow trench isolation region 16 in the device region 70. The shallow trench isolation region 18 in the device region 72 may extend to the maximum depth D1 relative to the top surface 13 of the semiconductor substrate 12 such that the bottom of the shallow trench isolation region 18 in the device region 72 is coplanar with the bottom of the shallow trench isolation region 16 and the bottom of the shallow trench isolation region 18.

With reference to FIG. 6 and in accordance with alternative embodiments of the invention, a trench 54 may be formed in a device region 74 as a recess that penetrates partially through the semiconductor layer 15 of the semiconductor substrate 12. The semiconductor layer 15 may be counter-doped with a p-type dopant, before the trench 54 is formed, using an ion implantation process. The trench 54 has a bottom 57 at given maximum depth D2 in the semiconductor layer 15 relative to the top surface 13 of the semiconductor substrate 12. In an embodiment, the maximum depth D2 of the trench 54 may be equal to the maximum depth D1 of the trench 22 (FIG. 2). The trench 54 may be patterned by lithography and etching processes. Similar to the sidewall 23 of the trench 22, the trench 54 has a sidewall 47 that extends partially through the shallow trench isolation region 16. The doped region 25 may be doped (e.g., heavily doped) with a concentration of a p-type dopant (e.g., boron) to provide p-type electrical conductivity.

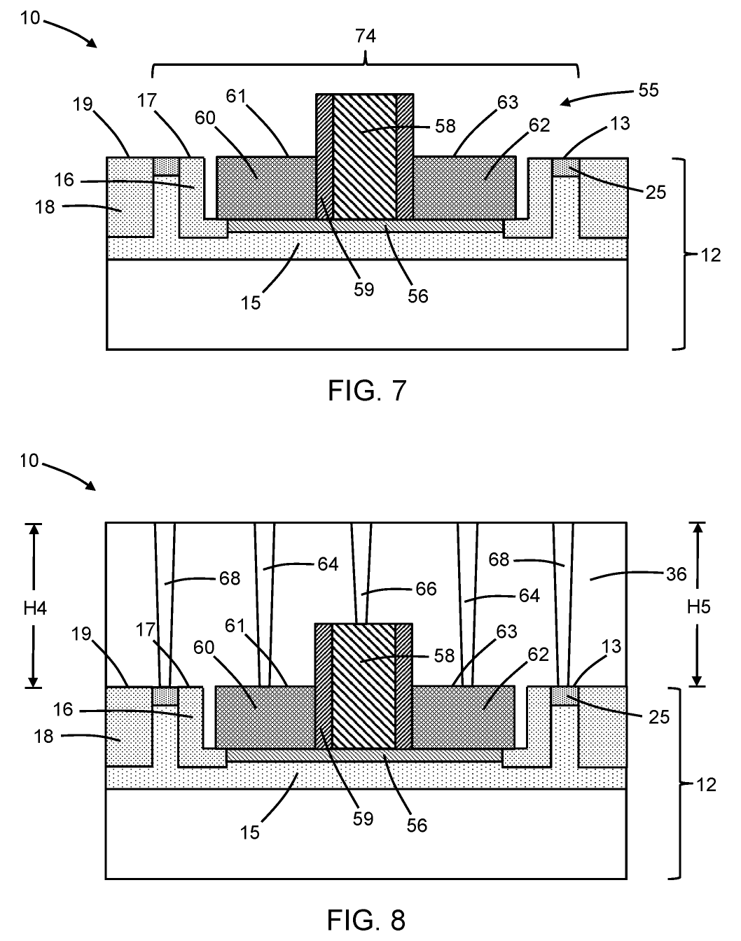

With reference to FIG. 7 in which like reference numerals refer to like features in FIG. 6 and at a subsequent fabrication stage, a base layer 56 of a heterojunction bipolar transistor 55 may be formed inside the semiconductor layer 15 adjacent to the bottom 57 of the trench 54 and an emitter 58 of the heterojunction bipolar transistor 55 may be formed inside the trench 22 with the emitter 58 positioned on the base layer 56. Dielectric spacers 65 comprised of an electrical insulator may be formed at the side edges of the emitter 58.

The base layer 56 may be formed by an ion implantation process. In an embodiment, the base layer 56 may be doped with a concentration of a dopant, such as a n-type dopant (e.g., arsenic or phosphorus) that provides n-type electrical conductivity. The emitter 58 may be comprised of a heavily-doped semiconductor material, such as polysilicon that is heavily doped with a concentration of a p-type dopant (e.g., boron) to provide p-type electrical conductivity. The emitter 58 may be formed by epitaxially growing or depositing a layer comprised of a semiconductor material and patterning the layer with lithography and etching processes.

The base layer 56 overlaps with an underlying portion of the semiconductor layer 15 providing the collector of the heterojunction bipolar transistor 55, and the emitter 58 overlaps with an underlying portion of the base layer 56. The base layer 56 is positioned in a vertical direction fully below the top surface 13 of the semiconductor substrate 12. The doped region 25 is coupled to the portion of the semiconductor layer 15 providing the collector of the heterojunction bipolar transistor 55 by a portion of the semiconductor layer 15 between the well 14 and the shallow trench isolation region 16.

Semiconductor layers 60, 62 are formed as raised features on respective sections of the base layer 56 that are exposed adjacent to the opposite sides of the emitter 58. Dielectric spacers 59 are positioned between the emitter 58 and the semiconductor layers 60, 62. The semiconductor layers 60, 62 may provide an extrinsic base of the heterojunction bipolar transistor 55 that is used to contact the base layer 56. The semiconductor layers 60, 62 may be comprised of a semiconductor material, such as silicon or silicon-germanium, and the semiconductor layers 60, 62 may be concurrently formed by a selective epitaxial growth process. The semiconductor layers 60, 62 may be doped (e.g., heavily doped) with a concentration of a dopant, such as an n-type dopant (e.g., arsenic or phosphorus) to provide n-type electrical conductivity.

The semiconductor layer 60 may have a top surface 61 that is separated from the base layer 56 by the full thickness of the semiconductor layer 60. The semiconductor layer 62 may have a top surface 63 that is separated from the base layer 56 by the full thickness of the semiconductor layer 62. In an embodiment, the top surface 61 may be coplanar or substantially coplanar with the top surface 63. In an embodiment, the top surface 61 may be coplanar with the top surface 13 of the semiconductor substrate 12. In an embodiment, the top surface 61 may be substantially coplanar with the top surface 13 of the semiconductor substrate 12. In an embodiment, the top surface 63 may be coplanar with the top surface 13 of the semiconductor substrate 12. In an embodiment, the top surface 63 may be substantially coplanar with the top surface 13 of the semiconductor substrate 12. In an embodiment, the top surface 61 and the top surface 63 may be coplanar with the top surface 13 of the semiconductor substrate 12. In an embodiment, the top surface 61 and the top surface 63 may be substantially coplanar with the top surface 13 of the semiconductor substrate 12.

With reference to FIG. 8 in which like reference numerals refer to like features in FIG. 7 and at a subsequent fabrication stage of the processing method, middle-of-line processing and back-end-of-line processing follow, which includes the formation of contacts 64, 66, 68 in the dielectric layer 36. The contacts 64 are coupled to the semiconductor layers 60, 62 of the heterojunction bipolar transistor 55, the contact 66 is coupled to the emitter 58 of the heterojunction bipolar transistor 55, and the contacts 68 are coupled by the doped region 25 to the collector of the heterojunction bipolar transistor 55 represented by the portion of the semiconductor layer 15 surrounding the base layer 56. The contacts 64, 66, 42 may be comprised of a metal, such as tungsten, and the top surfaces 61, 63, the portion of the top surface 13 over the doped region 25, and the emitter 58 may be capped by a silicide layer (not shown).

The contacts 64 may have a height H4 relative to the top surfaces 61, 63 of the semiconductor layers 60, 62, and the contacts 68 may have a height H5 relative to the top surface 13 of the semiconductor substrate 12 that is planar or substantially coplanar with the top surfaces 61, 63. In an embodiment, the height H4 may be equal to the height H5. In an embodiment, the height H4 may be substantially equal to the height H5.

In an embodiment, the height H4 and the height H5 may be equal to the height H3, the height H2, and/or the height H1 (FIGS. 4, 5). In an embodiment, the height H4 and the height H5 may be equal to the height H1. In an embodiment, the height H4 and the height H5 may be substantially equal to the height H1. In an embodiment, the height H4 and the height H5 may be equal to the height H2. In an embodiment, the height H4 and the height H5 may be substantially equal to the height H2. In an embodiment, the height H4 and the height H5 may be equal to the height H3. In an embodiment, the height H4 and the height H5 may be substantially equal to the height H3.

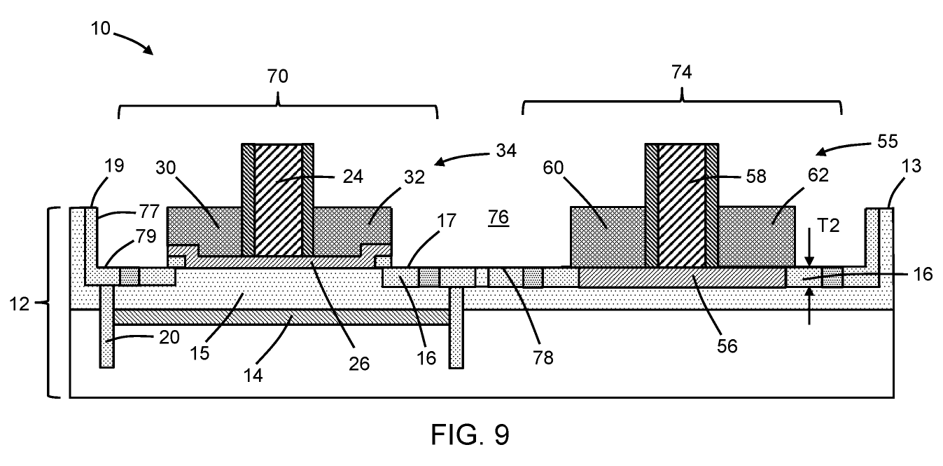

With reference to FIG. 9 and in accordance with alternative embodiments, the heterojunction bipolar transistor 34 and the heterojunction bipolar transistor 55 may be formed inside a shared trench 76. The trench 76 extends to a maximum depth at a bottom 78 that is less than the maximum depth D1 of the shallow trench isolation region 16 and the shallow trench isolation region 18 (FIG. 1). The trench 76 extends through a portion of the shallow trench isolation region 18. The shallow trench isolation region 18 has a non-recessed portion for which the top surface 19 remains coplanar with the top surface 13 of the semiconductor substrate 12. The shallow trench isolation region 18 has a portion that is recessed relative to the top surface 19 and the recessed portion has a top surface 79 that is coplanar with the surface of the portion of the semiconductor layer 15 of the semiconductor substrate 12 that adjoins the bottom 78 of the trench 76. The shallow trench isolation region 18 has a sidewall 77 that extends from the top surface 19 of the non-recessed portion to the top surface 79 of the recessed portion. The recessed portion of the shallow trench isolation region 18, which is reduced in thickness, may be considered to constitute an ultra-shallow trench isolation region. The shallow trench isolation region 18 overlaps with the deep trench isolation region 20, which is laterally offset from the sidewall 77.

The shallow trench isolation region 16 in the device region 70 and the shallow trench isolation region 16 in the device region 74 are shortened by the formation of the trench 76. The shortened shallow trench isolation regions 16 may have a thickness T2 relative to the surface of the semiconductor layer 15 at the bottom 78 of the trench 76. The thickness T2 is less than the thickness T1 of the shallow trench isolation region 18 in the device region 72 (FIG. 5).

The contacts 38, 40, 42 and the contacts 64, 66, 68 are subsequently formed. In an embodiment, the device region 72 for the field-effect transistor 44 (FIG. 5) may be arranged adjacent to either the device region 70 for the heterojunction bipolar transistor 34 or the device region 74 for the heterojunction bipolar transistor 55.

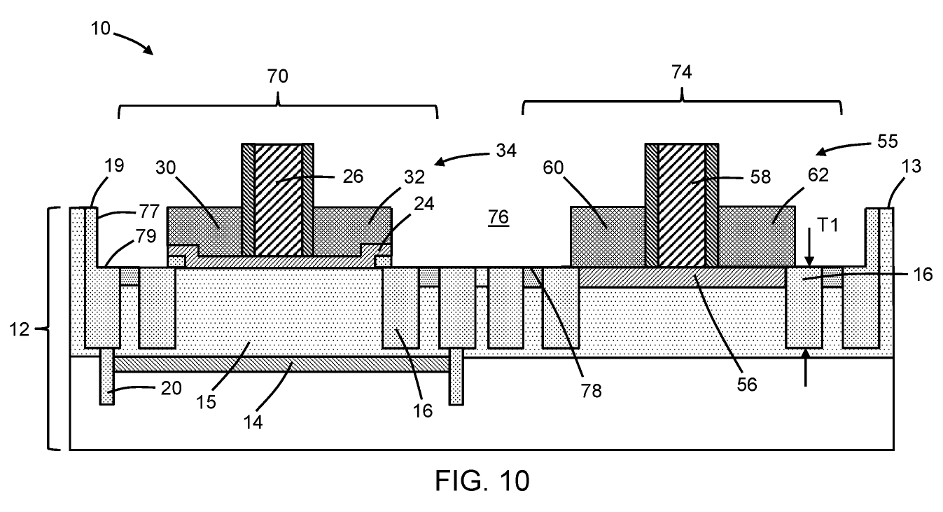

With reference to FIG. 10 and in accordance with alternative embodiments, the heterojunction bipolar transistor 34 and the heterojunction bipolar transistor 55 may be formed inside the trench 76. After the trench 76 is formed, the shallow trench isolation regions 16 may be formed. In an embodiment, the shallow trench isolation region 16 in the device region 70 and the shallow trench isolation region 16 in the device region 74 may have the same thickness T1 as the shallow trench isolation region 18 in the device region 72 (FIG. 5).

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. A feature may “overlie” another feature if the feature is positioned in elevation over another feature. A feature may “underlie” another feature if the feature is positioned in elevation below another feature. Different features may “overlap” if a feature extends over, and covers all or a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor substrate including a top surface and a trench having a bottom that is recessed relative to the top surface;
a first trench isolation region in the semiconductor substrate, the first trench isolation region including a first portion having a sidewall that surrounds the trench;
a second trench isolation region in the semiconductor substrate, the second trench isolation region surrounding the first trench isolation region, and the second trench isolation region spaced from the first portion of the first trench isolation region by a portion of the semiconductor substrate that adjoins the top surface; and
a first device structure including a first semiconductor layer inside the trench, a second semiconductor layer inside the trench, and a doped region in the portion of the semiconductor substrate, the first semiconductor layer and the second semiconductor layer adjoining along a first p-n junction.

2. The structure of claim 1 wherein the first portion of the first trench isolation region has a first surface that is coplanar with the top surface of the semiconductor substrate.

3. The structure of claim 2 wherein the first trench isolation region has a second portion laterally between the first portion and the first semiconductor layer of the first device structure.

4. The structure of claim 3 wherein the second portion of the first trench isolation region has a second surface that is coplanar with the bottom of the trench.

5. The structure of claim 1 wherein the first device structure is a heterojunction bipolar transistor.

6. The structure of claim 5 wherein the first semiconductor layer is a base of the heterojunction bipolar transistor, and the base is arranged in the trench below the top surface of the semiconductor substrate.

7. The structure of claim 6 wherein the heterojunction bipolar transistor includes a collector in the semiconductor substrate, the base layer adjoins the collector along a second p-n junction, and the portion of the semiconductor substrate is coupled to the collector.

8. The structure of claim 1 further comprising:
a field-effect transistor including a gate electrode on the top surface of the semiconductor substrate and a source/drain region adjoining the top surface of the semiconductor substrate.

9. The structure of claim 8 wherein the first portion of the first trench isolation region extends to a first maximum depth relative to the top surface of the semiconductor substrate, and further comprising:
a third trench isolation region in the semiconductor substrate, the third trench isolation region surrounding the field-effect transistor, the third trench isolation region extending to a second maximum depth relative to the top surface of the semiconductor substrate, and the second maximum depth equal to the first maximum depth.

10. The structure of claim 8 further comprising:
a first contact coupled to the doped region in the portion of the semiconductor substrate, the first contact having a first height relative to the top surface of the semiconductor substrate; and
a second contact coupled to the source/drain region, the second contact having a second height relative to the top surface of the semiconductor substrate, and the second height equal to the first height.

11. The structure of claim 8 wherein the first semiconductor layer is arranged in the trench below the top surface of the semiconductor substrate, and further comprising:
a third semiconductor layer on a portion of the first semiconductor layer, the third semiconductor layer having a top surface that is coplanar with the top surface of the semiconductor substrate.

12. The structure of claim 11 further comprising:
a first contact coupled to the doped region in the portion of the semiconductor substrate, the first contact having a first height relative to the top surface of the semiconductor substrate; and
a second contact coupled to the third semiconductor layer, the second contact having a second height relative to the top surface of the semiconductor substrate, and the second height equal to the first height.

13. A structure comprising:
a semiconductor substrate including a top surface and a trench having a bottom that is recessed relative to the top surface;
a first trench isolation region in the semiconductor substrate, the first trench isolation region including a first portion having a sidewall that adjoins the trench, and the first portion of the first trench isolation region extending from the top surface to a first maximum depth in the semiconductor substrate;
a first device structure including a first semiconductor layer inside the trench and a second semiconductor layer inside the trench, the first semiconductor layer and the second semiconductor layer adjoining along a first p-n junction; and
a second trench isolation region in the semiconductor substrate, the second trench isolation region laterally offset from the sidewall of the first portion of the first trench isolation region toward the first device structure, the second trench isolation region extending from the top surface of the semiconductor substrate to a second maximum depth in the semiconductor substrate, and the second maximum depth greater than the first maximum depth.

14. The structure of claim 13 further comprising:
a second device structure including a third layer inside the trench and a fourth layer inside the trench, the third layer and the fourth layer adjoining along a second p-n junction.

15. The structure of claim 13 wherein the first trench isolation region includes a second portion between the first portion and the first device structure, and the second portion of the first trench isolation region overlaps with the second trench isolation region.

16. The structure of claim 15 wherein the first portion of the first trench isolation region has a first surface that is coplanar with the top surface of the semiconductor substrate, and the second portion of the first trench isolation region has a second surface that is coplanar with the bottom of the trench.

17. The structure of claim 13 further comprising:
a field-effect transistor including a gate electrode on the top surface of the semiconductor substrate and a source/drain region adjoining the top surface of the semiconductor substrate; and
a third trench isolation region in the semiconductor substrate, the third trench isolation region surrounding the field-effect transistor, and the third trench isolation region having a first thickness.

18. The structure of claim 17 further comprising:
a fourth trench isolation region in the semiconductor substrate, the fourth trench isolation region surrounding the first device structure, and the fourth trench isolation region having a second thickness that is less than the first thickness.

19. The structure of claim 17 further comprising:
a fourth trench isolation region in the semiconductor substrate, the fourth trench isolation region surrounding the first device structure, and the fourth trench isolation region having a second thickness that is equal to the first thickness.

20. A method comprising:
forming a trench in a semiconductor substrate, wherein the semiconductor substrate has a top surface and the trench has a bottom that is recessed relative to the top surface;
forming a first trench isolation region in the semiconductor substrate, wherein the first trench isolation region includes a portion having a sidewall that surrounds the trench;
forming a second trench isolation region in the semiconductor substrate, wherein the second trench isolation region surrounds the first trench isolation region, and the second trench isolation region is spaced from the portion of the first trench isolation region by a portion of the semiconductor substrate that adjoins the top surface; and
forming a device structure including a first semiconductor layer inside the trench, a second semiconductor layer inside the trench, and a doped region in the portion of the semiconductor substrate, wherein the first semiconductor layer and the second semiconductor layer adjoin along a p-n junction.
